(19) United States
(12) Patent Application Publication
(10) Pub. No.: US 2003/0173597 A1
(43) Pub. Date: Sep. 18, 2003

(54) Semiconductor device

(75) Inventor: Toshiyuki Kamiya, Fujimi-machi (JP)

Correspondence Address: OLIFF & BERRIDGE, PLC, P.O. BOX 19928, ALEXANDRIA, VA, 22320, US

(73) Assignee: SEIKO EPSON CORPORATION, TOKYO (JP)

(21) Appl. No.: 10/329,685

(22) Filed: Dec. 27, 2002

(30) Foreign Application Priority Data
Jan. 16, 2002 (JP) 2002-007712

(51) Int. Cl. H01L 27/10

(52) U.S. Cl. 257/209

(57) ABSTRACT

A semiconductor device of the present invention includes a first interlayer dielectric formed over a semiconductor substrate, a fuse capable of being melted by irradiation of laser light, the fuse formed over the first interlayer dielectric, a first protective layer formed over the fuse, and a second interlayer dielectric formed over the first protective layer.

Japanese Patent Application No. 2002-7712 filed on Jan. 16, 2002, is hereby incorporated by reference in its entirety.

### BACKGROUND OF THE INVENTION

The present invention relates to a semiconductor device including a fuse.

A substitution circuit is incorporated in a semiconductor device in order to replace a defective circuit caused by a defect occurring during the manufacturing steps. In a semiconductor memory device, for example, most of the defects during the manufacturing steps occur in a memory cell section. Therefore, a plurality of redundant memory cells are generally provided in a unit of word lines or bit lines. A circuit which controls the redundant memory cells is called a redundant circuit. In the case where a defective element occurs in one chip which forms a semiconductor device, the redundant circuit causes a fuse having an address corresponding to the defective element to melt by irradiation of laser light, thereby switching the defective element to a normal element.

It is necessary to form an opening in a passivation layer in order to cause the fuses to melt. In this case, water or other pollutants may enter an interlayer dielectric from the opening in the passivation layer, thereby causing the fuse or a circuit interconnect to corrode, or characteristics of the semiconductor element to be changed. In recent years, accompanied by an increase in the degree of miniaturization and integration, there has been a case where a low dielectric constant film is used as the interlayer dielectric. Since the low dielectric constant film has high moisture permeability and high hygroscopicity, the above problems tend to occur. Therefore, the width of the interconnect used as the fuse and the interval between the adjacent interconnects must be increased in order to prevent occurrence of breakage or short circuits even if corrosion occurs to some extent. Moreover, a guard ring must be formed on the periphery of the opening in the passivation layer by using a metal interconnect layer in order to prevent water, pollutants, or the like from entering a region in which semiconductor elements and the circuit interconnects are formed.

However, the number of fuses is increased as the degree of miniaturization and integration of the semiconductor device is increased, whereby the area of the chip occupied by the fuse region is increased. This prevents reduction of the chip area and decreases the degree of freedom relating to the layout design.

### BRIEF SUMMARY OF THE INVENTION

The present invention may provide a semiconductor device in which reliability of a fuse is improved.

A semiconductor device according to the present invention comprises a first interlayer dielectric formed over a semiconductor substrate, a fuse capable of being melted by irradiation of laser light, the fuse formed over the first interlayer dielectric, a first protective layer formed over the fuse, and a second interlayer dielectric formed over the first protective layer.

### BRIEF DESCRIPTION OF THE SEVERAL VIEWS OF THE DRAWING

FIG. 1 is a view schematically showing a cross section of a semiconductor device of the present invention.

### DETAILED DESCRIPTION OF THE EMBODIMENT

A semiconductor device according to one embodiment of the present invention comprises a first interlayer dielectric formed over a semiconductor substrate, a fuse capable of being melted by irradiation of laser light, the fuse formed over the first interlayer dielectric, a first protective layer formed over the fuse, and a second interlayer dielectric formed over the first protective layer.

According to the semiconductor device of this embodiment, pollutants such as water or impurities can be prevented from entering the fuses by forming the first protective layer on the fuses, whereby corrosion can be avoided. In the case of forming fuses which are melted by using a laser, a passivation layer located above the fuses has an opening. Since the interlayer dielectric over the fuses is destroyed by the impact caused by melting the fuses, pollutants such as water or impurities enter from the top of the fuses in many cases. Specifically, the effect of preventing pollutants from entering the fuses can be increased by forming the first protective layer especially on the top of the fuses. Moreover, since the sides of the fuses are also covered with the first protective layer by forming the first protective layer on the fuses by using a conventional process, the effect of preventing pollutants from entering the fuses can be further increased.

(A) The semiconductor device of this embodiment may further comprise a second protective layer formed between the first interlayer dielectric and the fuses.

According to this configuration, pollutants such as water or impurities can be prevented from entering the fuses or semiconductor elements formed below the second protective layer by forming the second protective layer under the fuses. Moreover, a guard ring or the like is not necessarily formed. Furthermore, the effect of protecting the fuses is increased by covering the fuses with the first protective layer and the second protective layer.

(B) In the semiconductor device of this embodiment, at least one of the first protective layer and the second protective layer may have a diffusion rate of water or impurities lower than that of the second interlayer dielectric.

According to this configuration, diffusion of water or impurities can be reduced, whereby the effect of protecting the fuses can be increased.

(C) In the semiconductor device of this embodiment, at least one of the first protective layer and the second protective layer may be a silicon nitride film.

(D) In the semiconductor device of this embodiment, the second protective layer may have a thickness sufficient not to be destroyed when causing the fuses to melt.

(E) The semiconductor device of this embodiment may further comprise a circuit section including the interconnect layers forming a multi-layer structure, wherein the fuses may be formed in the same layer as one of the interconnect layers.

(F) In the semiconductor device of this embodiment, in the case of forming the fuses in the same layer as one of the interconnect layers in the circuit section, the fuses may be formed in the same layer as an uppermost layer of the interconnect layers.

(G) The semiconductor device of this embodiment may further comprise a passivation layer formed over the second interlayer dielectric, and an opening formed in the passivation layer above a region in which the fuses are formed, wherein at least one of the interconnect layers constituting the circuit section may be formed vertically under the opening and lower than the fuses.

According to this configuration, a layer lower than a region in which the fuses are formed can be used as a region which forms the circuit section. Therefore, the semiconductor device of the present invention can be easily miniaturized, and the degree of freedom relating to the layout design can be increased.

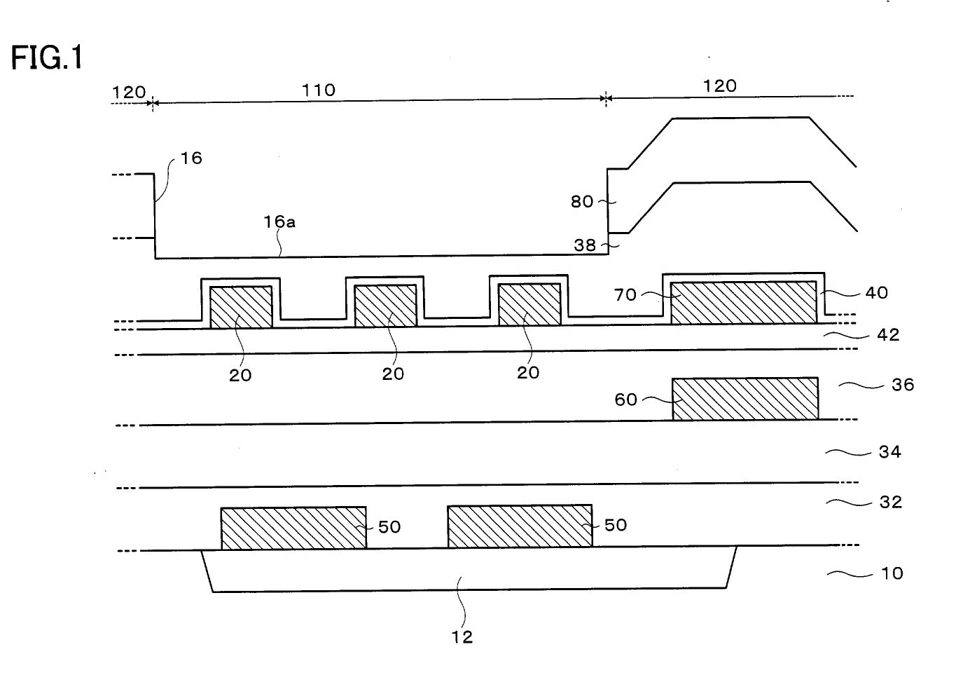

An embodiment of the present invention is described below with reference to the drawing. FIG. 1 is a cross-sectional view schematically showing a semiconductor device according to one embodiment of the present invention.

As shown in FIG. 1, the semiconductor device according to the present embodiment includes a circuit section 120 having a multi-layer interconnect structure, and a fuse section 110 including a plurality of fuses 20 which are melted by irradiation of laser light.

The circuit section 120 and the fuse section 110 are formed on a silicon substrate 10. The substrate is not limited to the silicon substrate insofar as the substrate has a semiconductor region. For example, a GaAs substrate, an SiGe substrate, an SOI substrate in which a thin film of a silicon layer is formed on an insulator, and the like can be given.

Interlayer dielectrics 32, 34, 36, and 38 in the first to fourth layers are formed on the silicon substrate 10 in that order from the silicon substrate 10. A first protective layer 40 and a second protective layer 42 are formed between the interlayer dielectric (first interlayer dielectric) 36 in the third layer and the interlayer dielectric (second interlayer dielectric) 38 in the fourth layer. The interlayer dielectrics 32, 34, 36, and 38 in the first to fourth layers may be formed of silicon oxide, FSG (fluorine-doped silicate glass), or a stacked layer of these compounds. In the present embodiment, the first protective layer 40 and the second protective layer 42 are formed between the interlayer dielectric 36 in the third layer and the interlayer dielectric 38 in the fourth layer. However, the present invention is not limited thereto. It suffices that the fuses 20 be located between the first protective layer 40 and the second protective layer 42.

Through holes (not shown) are formed at predetermined positions of the interlayer dielectrics 32, 34, 36, and 38 in the first to fourth layers. The through holes are filled with a conductive material, whereby contact sections (not shown) are formed. Interconnect layers formed on the top and bottom of each interlayer dielectric are electrically connected through the contact sections. A passivation layer 80 is formed of a silicon nitride film or the like on the interlayer dielectric 38 in the fourth layer.

The circuit section 120 is described below. The circuit section 120 includes a circuit having elements such as transistors. As examples of such a circuit, a memory circuit, a liquid crystal driver circuit, an analog circuit in which capacitors and resistance elements are formed, and the like can be given. As examples of the memory circuit, a DRAM, SRAM, flash memory, and the like can be given.

A plurality of interconnect layers (only interconnect layers 60 and 70 are shown in FIG. 1) electrically connected with transistors or other elements (not shown) which form a memory or the like included in the circuit section 120 are formed in the circuit section 120. In the semiconductor device shown in FIG. 1, the interconnect layer 60 is formed on the interlayer dielectric 34 in the second layer, and the interconnect layer 70 is formed on the second protective layer 42.

The fuse section 110 is described below. As shown in FIG. 1, the fuse section 110 is a region which is formed on the silicon substrate 10 and has an opening 16. The opening 16 is formed by etching a predetermined region of the semiconductor device to the middle of the interlayer dielectric 38. The fuses 20 are formed on the second protective layer 42. The first protective layer 40 is formed over the fuses 20. Specifically, the fuses 20 are located between the first protective layer 40 and the second protective layer 42. The bottom of the fuses 20 is covered with the second protective layer 42, and the top and the sides of the fuses 20 are covered with the first protective layer 40.

According to the semiconductor device of the present embodiment, the first protective layer 40 is formed on the interconnect layers which includes the fuses 20. Therefore, pollutants such as water or impurities can be prevented from entering the interconnect layers which forms the fuses 20, whereby occurrence of corrosion can be prevented.

In the case of forming the fuses 20 which is melted by using a laser, the passivation layer 80 located above the fuses 20 has an opening. The interlayer dielectric 38 over the fuses 20 is destroyed by the impact caused by melting the fuses 20. Therefore, pollutants such as water or impurities enter from the top of the fuses 20 in many cases. However, according to the present embodiment, since the first protective layer 40 is formed on the fuses 20, pollutants can be prevented from entering the interconnect layer. Moreover, since the second protective layer 42 is formed under the interconnect layers which includes the fuses 20, pollutants such as water or impurities can be prevented from entering interconnect layers and semiconductor elements formed below the fuses 20.

The first protective layer 40 and the second protective layer 42 are preferably formed of a layer having a diffusion rate of water or impurities lower than that of the interlayer dielectric 38 in the fourth layer. As the material for the first protective layer 40 and the second protective layer 42, a silicon nitride film may be used, for example. The first protective layer 40 has a thickness sufficient to ensure that the first protective layer 40 is not destroyed when causing the fuses 20 to melt. The first protective layer 40 has a thickness sufficient for preventing pollutants such as water or impurities from entering after causing the fuses 20 to melt. In more detail, the thickness of the first protective layer 40 is 100 to 200 nm. The second protective layer 42 has a thickness which does not prevent the fuses 20 from melting. In more detail, the thickness of the second protective layer 42 is 20 to 50 nm.

The interlayer dielectric 38 in the fourth layer is formed on the first protective layer 40. The fuses 20 covered with the first protective layer 40 and the second protective layer 42 are buried in the interlayer dielectric 38 in the fourth layer. The adjacent fuses 20 are insulated from each other by the interlayer dielectric 38 in the fourth layer.

In the semiconductor device shown in FIG. 1, the fuses 20 are formed in a layer at the same level as the interconnect layer 70 formed in the circuit section 120. The interconnect layer 70 and the fuses 20 may be formed by a single patterning step. Therefore, the interconnect layer 70 and the fuses 20 are formed on the second protective layer 42, have almost the same thickness, and are formed of the same material. For example, the interconnect layer 70 and the fuses 20 may be formed of aluminum, copper, polysilicon, tungsten, or titanium.

In the present embodiment, one of the interconnect layers which form the circuit section 120 is formed under the fuses 20. In this case, water or pollutants can be prevented from entering the interconnect layer by the presence of the first protective layer 40 and the second protective layer 42.

In the semiconductor device shown in FIG. 1, high-melting-point metal nitride layers (not shown) are formed on the top and bottom of the fuses 20. High-melting-point metal nitride layers (not shown) are also formed on the top and bottom of the interconnect layers 60 and 70 which form the circuit section 120.

The high-melting-point metal nitride layers on the top and bottom of the interconnect layers 60 and 70 are formed to improve reliability (stress migration resistance, electro-migration resistance, and the like) of the interconnect layers 60 and 70. The nitride layers formed on the top of the interconnect layers 60 and 70 are utilized as antireflection films in a photolithography step for processing the interconnect layers 60 and 70.

An example of a method of manufacturing the semiconductor device of the present embodiment shown in FIG. 1 is described below.

An element isolation region 12 is formed in the silicon substrate 10. A resist (not shown) having a predetermined pattern is formed on the substrate 10. A well (not shown) is formed at a predetermined position of the substrate 10 by ion implantation. Transistors (not shown) are formed in the circuit section 120 on the silicon substrate 10. A silicide layer (not shown) containing a high melting point metal such as titanium or cobalt is formed by using a conventional salicide technology. A stopper layer (not shown) containing a silicon nitride film as a major component is formed by using a plasma CVD method or the like.

Interconnect layers 50 and the fuses 20 are formed in the fuse section 110, and the interconnect layers including the interconnect layers 60 and 70 (only the interconnect layers 60 and 70 are shown in FIG. 1) are formed in the circuit section 120. The interlayer dielectrics 32, 34, and 36 in the first to third layers, the second protective layer 42 and the first protective layer 40 formed of a silicon nitride film, and the interlayer dielectric 38 in the fourth layer are formed corresponding to each step. The interlayer dielectrics 32, 34, 36, and 38 in the first to fourth layers are formed by using an HDP method, an ozone TEOS (tetraethylorthosilicate) method, a plasma CVD method, a coating method such as a spin coating method (method utilizing SOG), or the like. The interlayer dielectrics 32, 34, 36, and 38 are optionally planarized by using a CMP method. The first protective layer 40 is formed by using a plasma CVD method, a thermal CVD method, or the like. A stacked film consisting of the silicon nitride film and an oxynitride film or a silicon nitride film may be used as the first protective layer 40.

The fuses 20 are formed in a layer at the same level and in the same step as the interconnect layer 70. Specifically, the fuses 20 and the interconnect layer 70 are formed on the second protective layer 42 and formed of the same material.

The formation step of the fuses 20 is described below.

After forming the interlayer dielectrics 32, 34, and 36 in the first to third layers, a layer of a silicon nitride film which becomes the second protective layer 42 is formed on the interlayer dielectric 36 in the third layer. A high-melting-point metal nitride layer such as a titanium nitride layer, a metal layer containing aluminum, a stacked layer of a high-melting-point metal layer such as a titanium layer and a high-melting-point metal nitride layer such as a titanium nitride layer (neither of these layers are shown in FIG. 1) are formed on the second protective layer 42 by sputtering. These layers are patterned into a predetermined shape. The fuses 20 and the interconnect layer 70 are formed of a metal layer containing aluminum by this step. A high-melting-point metal nitride layer is formed on the bottom of the fuses 20 and the interconnect layer 70. A high-melting-point metal nitride layer consisting of a stacked layer of a high-melting-point metal nitride layer and a high-melting-point metal layer is formed on the top of the fuses 20 and the interconnect layer 70. A layer of a silicon nitride film which becomes the first protective layer 40 is formed on the fuses 20 and the interconnect layer 70. The formation method and the material for the first protective layer 40 are the same as the second protective layer 42.

The contact sections (not shown) for electrically connecting the interconnect layers are formed in each interlayer dielectric. The contact sections are formed by forming contact holes (not shown) through each interlayer dielectric, and filling the contact holes with a conductive material by sputtering or the like. After forming the interlayer dielectric 38 in the fourth layer, the passivation layer 80 is formed on the interlayer dielectric 38 in the fourth layer. The passivation layer 80 is formed of a silicon nitride film or the like.

The opening 16 is formed by etching a predetermined region of the semiconductor device from the side of the passivation layer 80 to the middle of the interlayer dielectric 38 in the fourth layer, as shown in FIG. 1. In this step, the opening 16 is formed so that the fuses 20 are located under a bottom 16a of the opening 16. The interlayer dielectric 38 in the fourth layer is etched so that the top of the fuses 20 is covered with the interlayer dielectric 38 in the fourth layer, as shown in FIG. 1. Specifically, the interlayer dielectric 38 in the fourth layer is etched so that at least the fuses 20 are not exposed.

As described above, according to the semiconductor device of the present invention, since the periphery of the fuses 20 is covered with the first protective layer 40 and the second protective layer 42 formed of a silicon nitride film or the like which excels in moisture resistance, corrosion of the interconnects caused by incoming water or the like can be prevented. In the case of forming the interlayer dielectric 38 in the fourth layer using an SOG film, since the SOG film has high hygroscopicity, a problem relating to reliability of the fuse may occur. However, according to the semiconductor device of the present invention, occurrence of such a problem can be avoided.

In the case of providing an interconnect layer which forms the circuit section such as the interconnect layer 50 at a lower part of the fuse section 110, the first protective layer 40 prevents water or pollutants from entering the interconnect layer, whereby reliability of the interconnect layer can be increased.

The present invention is not limited to the present embodiment. For example, a guard ring may be provided to surround the opening 16 in the fuse section. The case where the fuses 20 are formed in a layer at the same level as the uppermost interconnect layer of the interconnect layers which form the circuit section 120 is described above. However, the layer in which the fuses 20 are formed is not limited to this layer. The fuses 20 may be formed in a layer at the same level as another interconnect layer.

What is claimed is:

1. A semiconductor device comprising:
a first interlayer dielectric formed over a semiconductor substrate;
a fuse capable of being melted by irradiation of laser light, the fuse formed over the first interlayer dielectric;
a first protective layer formed over the fuse; and
a second interlayer dielectric formed over the first protective layer.

2. The semiconductor device as defined in claim 1,
wherein a diffusion rate of water of the first protective layer is lower than a diffusion rate of the second interlayer dielectric.

3. The semiconductor device as defined in claim 1,
wherein a diffusion rate of impurities of the first protective layer is lower than a diffusion rate of the second interlayer dielectric.

4. The semiconductor device as defined in claim 1,
wherein the first protective layer is a silicon nitride film.

5. The semiconductor device as defined in claim 1, further comprising:
a second protective layer formed between the first interlayer dielectric and the fuse.

6. The semiconductor device as defined in claim 5,
wherein a diffusion rate of water of the second protective layer is lower than a diffusion rate of the second interlayer dielectric.

7. The semiconductor device as defined in claim 5,
wherein a diffusion rate of impurities of the second protective layer is lower than a diffusion rate of the second interlayer dielectric.

8. The semiconductor device as defined in claim 5,
wherein the second protective layer is a silicon nitride film.

9. The semiconductor device as defined in claim 5,
wherein the second protective layer has a thickness sufficient not to be destroyed when causing the fuse to melt.

10. The semiconductor device as defined in claim 1, further comprising:
a circuit section including the interconnect layers forming a multi-layer structure,
wherein the fuse is formed in the same layer as one of the interconnect layers.

11. The semiconductor device as defined in claim 10,
wherein the fuse is formed in the same layer as an uppermost layer of the interconnect layers.

12. The semiconductor device as defined in claim 10, further comprising:
a passivation layer formed over the second interlayer dielectric, and
an opening formed in the passivation layer above a region in which the fuse is formed,
wherein at least one of the interconnect layers constituting the circuit section is formed vertically under the opening and lower than the fuse.

13. The semiconductor device as defined in claim 10, further comprising:
a second protective layer formed between the first interlayer dielectric and the interconnect layers including the fuse.

14. The semiconductor device as defined in claim 11, further comprising:
a second protective layer formed between the first interlayer dielectric and the interconnect layers including the fuse.

15. The semiconductor device as defined in claim 12, further comprising:
a second protective layer formed between the first interlayer dielectric and the interconnect layers including the fuse.
